(19) United States
(12) Patent Application Publication
(10) Pub. No.: US 2021/0134690 A1
(43) Pub. Date: May 6, 2021

(54) SEMICONDUCTOR DEVICE PACKAGES AND METHODS OF MANUFACTURING THE SAME

(71) Applicant: Advanced Semiconductor Engineering, Inc., Kaohsiung (TW)

(72) Inventor: Yi CHEN, Kaohsiung (TW)

(73) Assignee: Advanced Semiconductor Engineering, Inc., Kaohsiung (TW)

(21) Appl. No.: 16/671,956

(22) Filed: Nov. 1, 2019

(51) Int. Cl. H01L 23/16; H01L 23/31; H01L 23/498; H01L 21/48

(52) U.S. Cl. CPC H01L 23/16; H01L 21/481; H01L 23/49833; H01L 23/3121

(57) ABSTRACT

A semiconductor device package includes a substrate and an interposer. A bottom surface of the interposer is attached to a top surface of the substrate by a conductive adhesive layer including a spacer.

### BACKGROUND

### 1. Field of the Disclosure

The present disclosure relates to semiconductor device packages and methods of manufacturing the same.

### 2. Description of Related Art

In a three-dimensional (3D) stacked semiconductor structure, interposers are usually arranged between two stacked semiconductor substrates to support the substrates and provide electrical connection therebetween. The interposers creates a gap between the substrates for accommodating semiconductor devices. The configuration and arrangement of the interposers affect available surface area of the substrates for disposing semiconductor devices. In addition, to have a superior uniformity, the gap should be well controlled to reduce stand-off deviation.

### SUMMARY

According to some embodiments of the present disclosure, a semiconductor device package includes a first substrate and a first interposer. A bottom surface of the first interposer is attached to a top surface of the first substrate by a first conductive adhesive layer including a spacer.

According to some embodiments of the present disclosure, a method of manufacturing a semiconductor device package includes providing a first substrate, providing an interposer, and forming a spacer in contact with the first substrate and the interposer.

### BRIEF DESCRIPTION OF THE DRAWINGS

Aspects of the present disclosure are readily understood from the following detailed description when read with the accompanying figures. It should be noted that various features may not be drawn to scale. In fact, the dimensions of the various features may be arbitrarily increased or reduced for clarity of discussion.

FIG. 1 is a cross-sectional view of a semiconductor device package in accordance with some embodiments of the present disclosure.

FIG. 2 is a cross-sectional view of another semiconductor device package in accordance with some embodiments of the present disclosure.

FIG. 3A is an enlarged view of the area CS as shown in FIG. 2 according to some embodiments of the present disclosure.

FIG. 3B is an enlarged view of the area CS as shown in FIG. 2 according to some embodiments of the present disclosure.

FIG. 4A is a top view of an interposer in accordance with some embodiments of the present disclosure.

FIG. 4B is another top view of an interposer in accordance with some embodiments of the present disclosure.

FIG. 4C is another top view of an interposer in accordance with some embodiments of the present disclosure.

FIG. 4D is another top view of an interposer in accordance with some embodiments of the present disclosure.

FIG. 5A, FIG. 5B, FIG. 5C and FIG. 5D illustrate various stages of a method for manufacturing a semiconductor device package in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

The following disclosure provides for many different embodiments, or examples, for implementing different features of the provided subject matter. Specific examples of components and arrangements are described below. These are, of course, merely examples and are not intended to be limiting. In the present disclosure, reference to the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Embodiments of the present disclosure are discussed in detail below. It should be appreciated, however, that the present disclosure provides many applicable concepts that can be embodied in a wide variety of specific contexts. The specific embodiments discussed are merely illustrative and do not limit the scope of the disclosure.

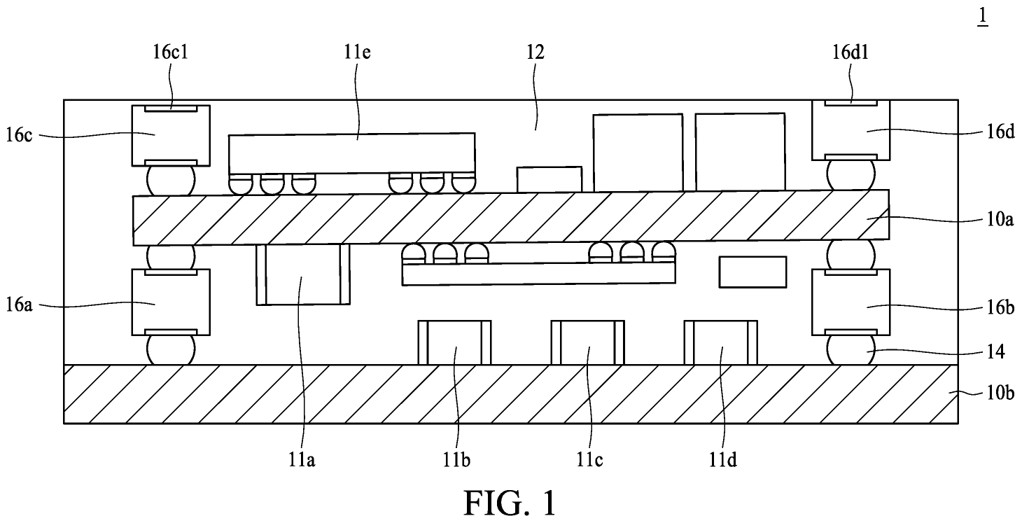

FIG. 1 is a cross-sectional view of a semiconductor device package 1 in accordance with some embodiments of the present disclosure. The semiconductor device package 1 includes substrates 10a and 10b, a plurality of electronic components 11a, 11b, 11c, 11d and 11e and a plurality of interposers 16a, 16b, 16c and 16d.

Each of the electronic components 11a, 11b, 11c, 11d and 11e and the other electronic components shown but not denoted in FIG. 1 may include one or more passive electronic components, such as a capacitor, a resistor or an inductor; and/or one or more active electronic components, such as a processor component, a switch component or an integrated circuit (IC) chip. Each electronic component may be electrically connected to one or more of another electronic component and to the substrate 10a or 10b, and electrical connection may be attained, e.g., by way of flip-chip or other techniques.

Referring to FIG. 1, one or more electronic components, e.g., 11b, 11c and 11d, are disposed on a top surface of the substrate 10b. One or more electronic components, e.g., 11a, are disposed on a bottom surface of the substrate 10a and one or more electronic components, e.g., 11e, are disposed on a top surface of the substrate 10a.

The interposers 16a and 16b may be disposed between the substrate 10a and the substrate 10b to separate the two substrates 10a and 10b and define a space for accommodating the electronic components (e.g., 11b, 11c and 11d) disposed on the top surface of the substrate 10b and the electronic components (e.g., 11a) disposed on the bottom surface of the substrate 10a. Each of the interposers 16a and 16b has a plurality of pads arranged at its top surface and a plurality of pads arranged at its bottom surface and provides electrical connection between the two substrates 10a and 10b. In some embodiments, additional interposers (e.g., 16c and 16d) may be disposed on the top surface of the substrate 10a to electrically connect the substrate 10a to a further substrate or other device.

The encapsulation layer 12 covers or encapsulates the electronic components 11a, 11b, 11c, 11d and 11e, the interposers 16a, 16b, 16c and 16d and the substrates 10a and 10b. The encapsulation layer 12 may include an epoxy resin including filler therein, a molding compound (e.g., an epoxy molding compound or other molding compound), a polyimide, a phenolic compound or material, a material including a silicone dispersed therein, or a combination thereof.

In some comparative embodiments, the attachment of interposers 16a, 16b, 16c and 16d is achieved by using solder paste (e.g., layer 14), and thus, several reflow processes are performed. However, the dimension (e.g., a height) of the solder paste layer 14 may decrease after every reflow process. Therefore, it is difficult to control the height of each solder paste layer, which results in stand-off deviation especially for the case where independent interposers are used at the same tier. Due to the stand-off deviation, the substrate 10a is tilted and it is difficult to maintain the interposers 16c and 16d formed on the top surface of the substrate 10a at the same height. Some of the topmost I/O pads (for example, the pad 16c1 of the interposer 16c) may thus be buried after applying the encapsulation layer 12, which adversely affects reliability and performance of the semiconductor device package 1.

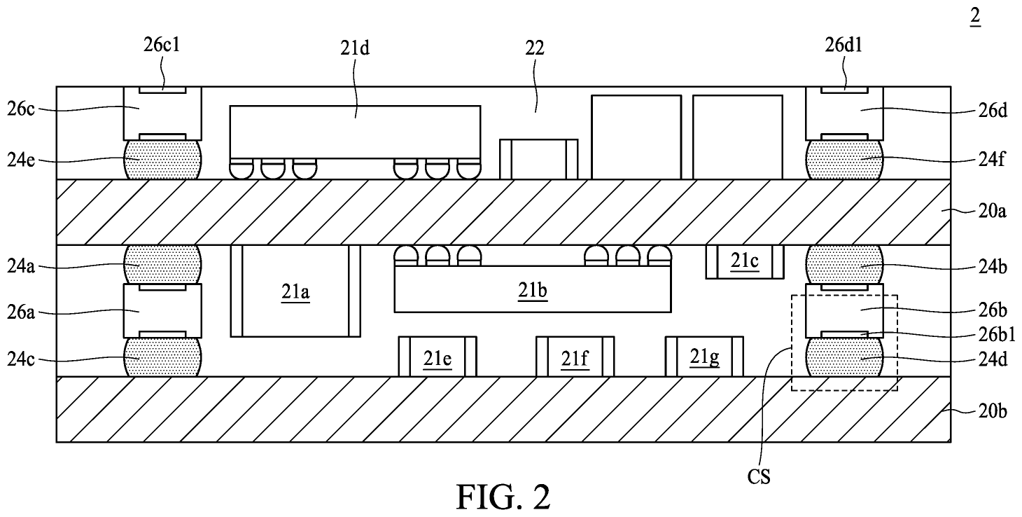

FIG. 2 is a cross-sectional view of another semiconductor device package 2 in accordance with some embodiments of the present disclosure. The semiconductor device package 2 is a stacked structure which may include substrate(s), e.g., 20a and 20b; electronic component(s), e.g., 21a, 21b, 21c, 21d, 21e, 21f and 21g; and interposer(s), e.g., 26a, 26b, 26c and 26d. The substrates may include traces, pads or interconnections (not shown) for electrical connection.

As shown in FIG. 2, one or more electronic components, e.g., 21a, 21b and 21c, may be disposed on a bottom surface of the substrate 20a. One or more electronic components, e.g., 21d, may be disposed on a top surface of the substrate 20a. One or more electronic components, e.g., 21e, 21f and 21g, may be disposed on a top surface of the substrate 20b.

Each of the electronic components 21a, 21b, 21c, 21d, 21e, 21f and 21g may include one or more passive electronic components and/or one or more active electronic components as discussed hereinabove.

In some embodiments, the semiconductor device package 2 includes a first substrate 20b and a first interposer 26a or 26b. The first interposer 26a or 26b is disposed on a top surface of the first substrate 20b. A bottom surface of the interposer 26a or 26b is attached to to the top surface of the substrate 20b by a first conductive adhesive layer 24c or 24d and the first conductive adhesive layer 24c or 24d includes a spacer. In some embodiments, the spacer is in direct contact with the first substrate 20b and a respective first interposer 26a or 26b. The first interposer 26a or 26b has a plurality of pads arranged at its bottom surface to provide electrical connection to the substrate 20b. The semiconductor device package 2 may include at least one first interposer, or at least two first interposers, at least three first interposers, or more first interposers which are separated apart from each other.

In some embodiments, the semiconductor device package 2 further includes a second substrate 20b. A top surface of the interposer 26a or 26b is attached to a bottom surface of the second substrate 20b by a second conductive adhesive layer 24a or 24b. In some embodiments, the second conductive adhesive layer 24a or 24b includes a spacer. In some embodiments, the spacer is in direct contact with the second substrate 20a and a respective first interposer 26a or 26b. The first interposer 26a or 26b has a plurality of pads arranged at its top surface to provide electrical connection to the second substrate 20a.

In some embodiments, the semiconductor device package 2 further includes a second interposer 26c or 26d. The second interposer 26c or 26d is attached to a top surface of the second substrate 20a by a third conductive adhesive layer 24e or 24f In some embodiments, the third conductive adhesive layer 24e or 24f includes a spacer. In some embodiments, the spacer is in direct contact with the second substrate 20a and a respective second interposer 26c or 26d. The second interposer 26a or 26b has a plurality of pads arranged at its bottom surface to provide electrical connection to the substrate 20a. The semiconductor device package 2 may include at least one second interposer, or at least two second interposers, at least second interposers, or more second interposers which are separated apart from each other.

In some embodiments, the semiconductor device package 2 further includes an encapsulation layer 22. The encapsulation layer 22 covers or encapsulates the electronic components 21a, 21b, 21c, 21d, 21e, 21f and 21g, the interposers 26a, 26b, 26c and 26d, the conductive adhesive layer 24a, 24b, 24c, 24d, 24e and 21f, the substrates 20a, and the substrate 20b. The encapsulation layer 22 may include an epoxy resin including filler therein, a molding compound (e.g., an epoxy molding compound or other molding compound), a polyimide, a phenolic compound or material, a material including a silicone dispersed therein, or a combination thereof.

The interposers 26a, 26b, 26c and 26d are independent from each other. The semiconductor device package may include one, two, three or more interposers, which are separated apart from each other, at the same tier (e.g., the interposers 26a and 26b and the interposers 26c and 26d). The shape of interposers are not particularly limited. In some embodiments, the interposer(s) may have a strip shape or a strip-like shape. In some embodiments, to increase available surface area of the substrates for disposing electronic components and to maintain the balance of the substrate to be stacked above, at least two interposers having a strip shape may be used.

The conductive adhesive layers 24a, 24b, 24c, 24d, 24e and 24f are independent from each other and may be made of the same or different material. The conductive adhesive layers may be made of a soldering, conductive material. In some embodiments, the soldering, conductive material may include a thermosetting resin. In some embodiments, the soldering, conductive material may include a thermosetting resin and an electrically conductive material. The thermosetting resin may be epoxy resin, acrylate, polyimide, silicon resin, etc. The electrically conductive material may be metal powders, such as gold, silver, or copper. The thermosetting resin may be a B-stage resin.

The conductive adhesive layers may include a spacer or be formed into a spacer in situ. The spacer to be added to the conductive adhesive layers may be conductive or non-conductive, which, for example, can be a metallic, plastic or glass spacer. The spacer may include copper-cored bump or ball, a plastic-cored bump or ball, or a glass ball. The size of the spacer can be designed to control the gap between the interposer and the substrate. In some embodiments, the spacer may have an average diameter of 60 μm or more, 80 μm or more, 90 μm or more, 100 μm or more, 110 μm or more, 120 μm or more, 130 μm or more, 150 μm or more, 180 μm or more, 200 μm or more, 220 μm or more, 250 μm or more, or 300 μm or more.

In some embodiments, the soldering, conductive material may be metal paste (such as copper paste) includes metal powders (such as copper powders) as electrically conductive material and thermosetting resin (such as epoxy) as a binder. A total volume of the spacers is more than about 2% of a volume of the metal paste (e.g. about 3% or more of the volume of the metal paste, about 4% or more of the volume of the metal paste, or about 5% or more of the volume of the paste), and a total volume of the metal powders and the thermosetting resin is less than about 98% of the volume of the metal paste (e.g. about 97% or less of the volume of the metal paste, about 96% or less of the volume of the metal paste, or about 95% or less of the volume of the metal paste).

In the following paragraphs, the structure of the interposers is further illustrated by referring to the interposer 26b. However, it should be noted that other interposers may have the same or similar structure.

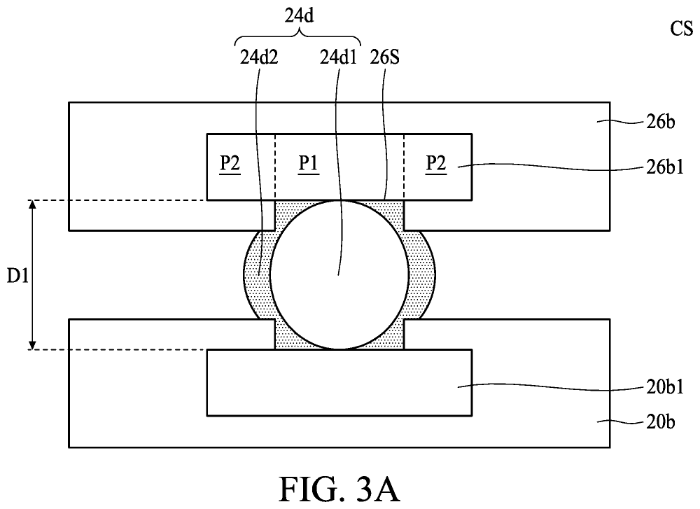

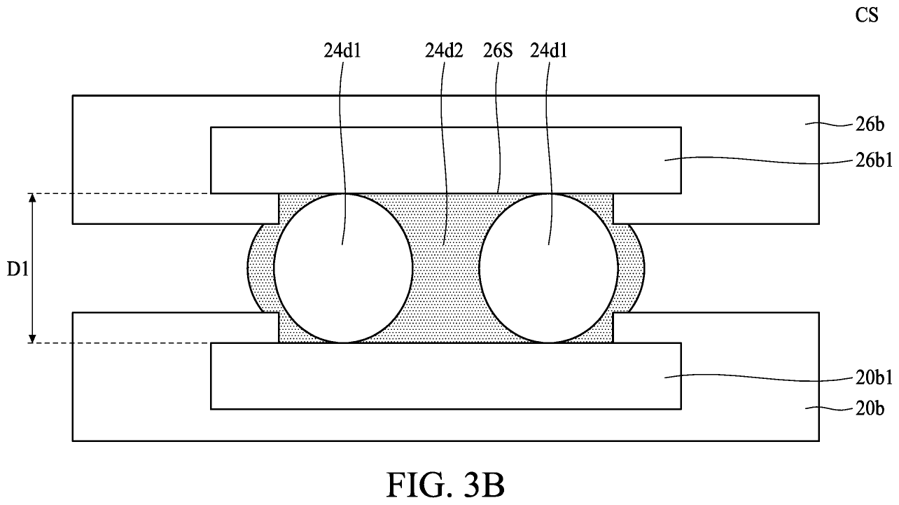

FIG. 3A is an enlarged view of the area CS as shown in FIG. 2 according to some embodiments of the present disclosure. The first interposer 26b includes a pad 26b1 at the bottom surface of the interposer 26b. The pad 26b1 is arranged at or embedded within the bottom surface of the interposer 26b. The substrate 20b includes a pad 20b1 at the top surface of the substrate 20b. The pad 20b1 is arranged at or embedded within the top surface of the substrate 20b. The gap D1 is generated between the exposed surface of the pad 26b1 and the exposed surface of the pad 20b1.

As depicted in FIG. 3A, the interposer 26 has a recess at the bottom surface of the interposer 26 and the pad 26b1 of the interposer 26 is exposed from the recess. The pad 26b1 includes a central region P1 and a peripheral region P2 surrounding the central region P1. The first interposer 26b includes an insulation layer 28 (not denoted in FIG. 3A) disposed at the bottom surface of the first interposer 26b and covering the peripheral region P2 of the pad 26b1. The central region P1 of the pad 26b1 is exposed from the insulation layer 28 and has an exposed surface 26S. The insulation layer 28 and the exposed surface 26S of the pad 26b1 define the recess. Similarly, the substrate 20b may have a recess to expose a central region of the pad 20b1 of the substrate 20b.

The recess of the interposer 26b accommodates the conductive adhesive layer 24d, or in some embodiments, the recess of the first interposer 26b together with the recess of the substrate 20b accommodate the conductive adhesive layer 24d. The conductive adhesive layer 24d may include a spacer 24d1 covered or surrounded by the thermosetting resin 24d2, or in some embodiments, the conductive adhesive layer 24d constitutes a spacer. The spacer can be in direct contact with the exposed surface 26S of the pad 26b1. The spacer can be in direct contact with the substrate 20b (e.g., the exposed surface of the pad 20b1). In some embodiments, the exposed surface 26S of the pad of the interposer and the exposed surface of the pad of the substrate are substantially the same or greater than the average diameter of the spacer.

FIG. 3B is an enlarged view of the area CS as shown in FIG. 2 according to some embodiments of the present disclosure. The enlarged view CS of FIG. 3B is similar to that of FIG. 3A except that in FIG. 3B, the conductive adhesive layer 24d includes two spacers.

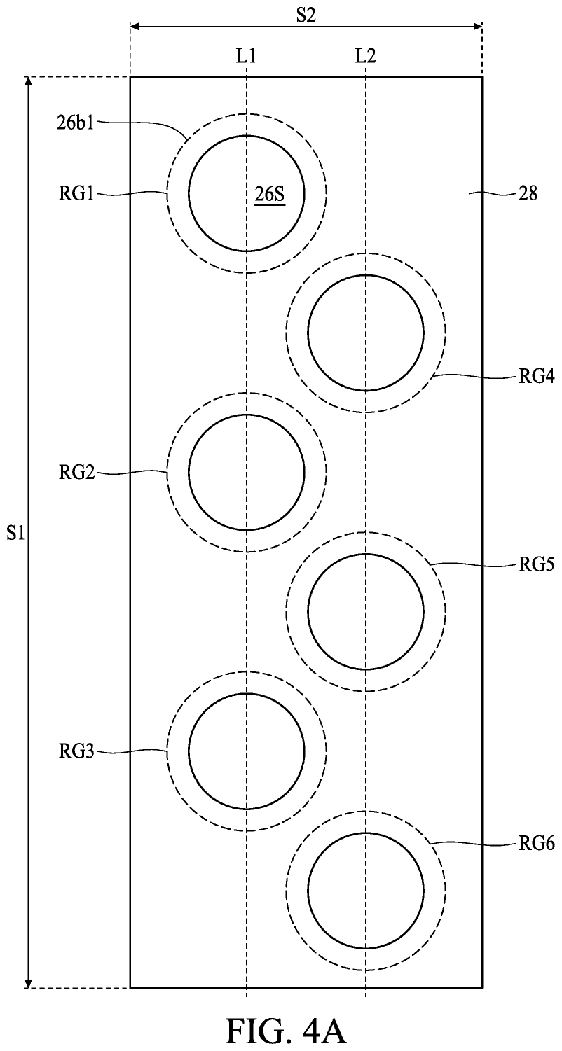

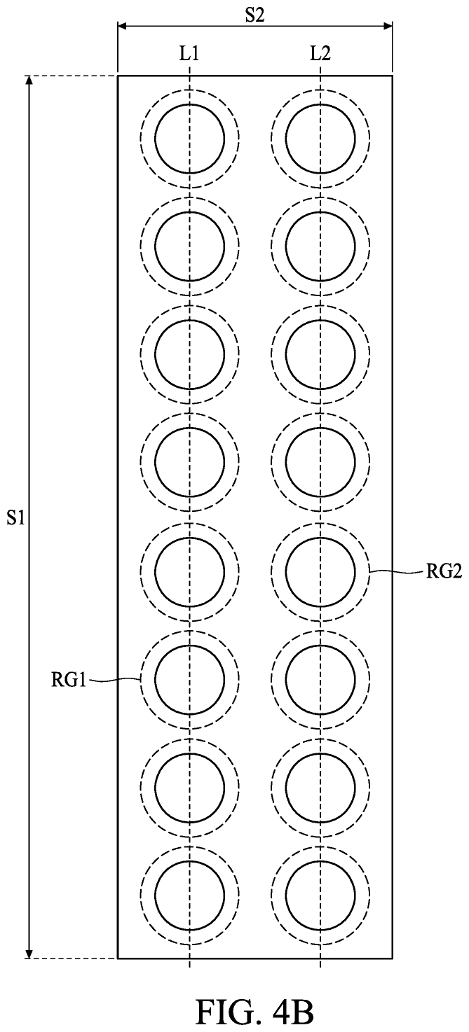

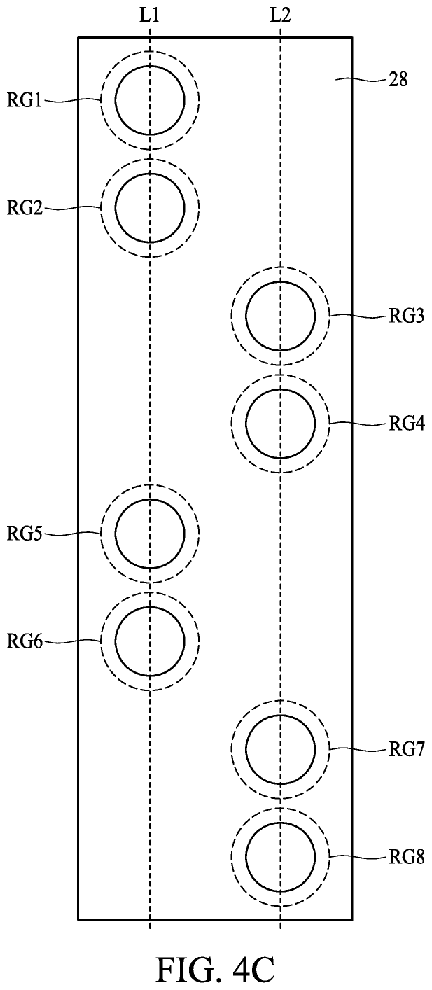

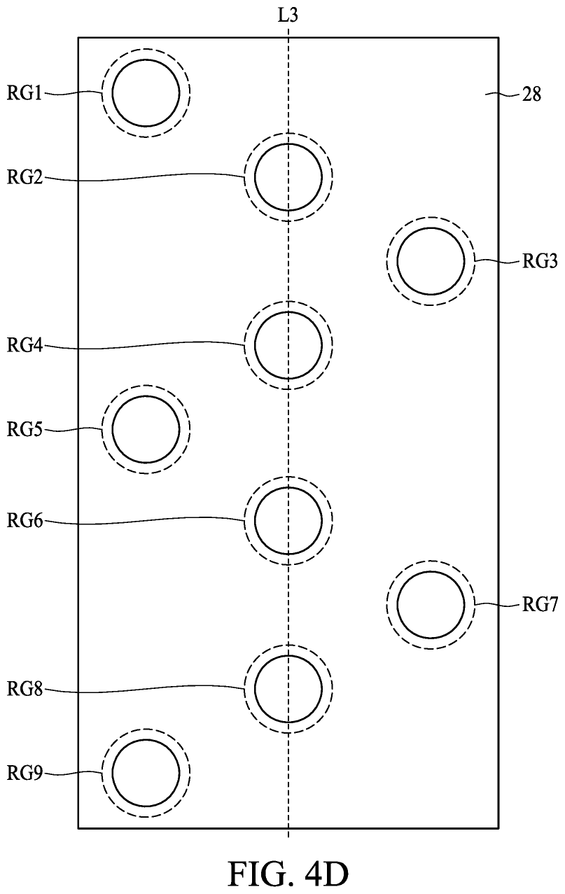

FIG. 4A, FIG. 4B, FIG. 4C and FIG. 4D illustrate the arrangement of the pads in the interposer in accordance with some embodiments of the present disclosure. The arrangement of the plurality of the pads to be discussed below can further improve the tilt issue of the stacked structure.

FIG. 4A is a top view of an interposer in accordance with some embodiments of the present disclosure. As shown in FIG. 4A, the interposer has a strip structure or a strip-like structure with a length S1 and a width S2. The interposer includes a plurality of pads, e.g., RG1, RG2, RG3, RG4, RG5 and RG6. The pads RG1, RG2, RG3, RG4, RG5 and RG6 are separated apart from each other and can be arranged regularly or irregularly. The insulation layer 18 is disposed at the top surface of the interposer and covers the peripheral region of the pads. The central region of the pads is exposed from the insulation layer 28 and has an exposed surface 26S.

In FIG. 4A, the pads RG1, RG2, RG3, RG4, RG5 and RG6 are arranged in a staggered manner or a staggered-like manner. In some embodiments, the pads RG1˜RG6 are arranged in two lines (e.g., L1 and L2), three lines, four lines or more lines, which are substantially in parallel with each other and extending along the length direction S1.

FIG. 4B is another top view of an interposer in accordance with some embodiments of the present disclosure. The top view of FIG. 4B is similar to FIG. 4A except that in FIG. 4B, the pads are arranged in two or more lines (e.g., L1 and L2) which are substantially in parallel with each other, but not in a staggered manner. The center of the pads locates at one of the lines.

FIG. 4C is another top view of an interposer in accordance with some embodiments of the present disclosure. The top view of FIG. 4C is similar to FIG. 4B except that in FIG. 4C, two pads (RG1 and RG2) are arranged in line L1, followed by, in sequence: two pads (RG3 and RG4) arranged in line L2, two pads (RG5 and RG6) arranged in line L1, two pads (RG7 and RG8) arranged in line L2, etc.

FIG. 4D is another top view of an interposer in accordance in accordance with some embodiments embodiments of the present disclosure. In FIG. 4D, a portion of the pads RG2, RG4, RG6 and RG8 are arranged in a central line L3, and the other portion of the pads RG1, RG3, RG5, RG7 and RG9 are arranged aside the central line L3. The pads RG1, RG3, RG5, RG7 and RG9 may be arranged regularly or irregularly.

By disposing the interposer between the substrates and using the spacer to secure a desirable distance between the substrate and the interposer, the interposers disposed at the same tier can be well-controlled and a distance between the bottom surface of the upper substrate and the top surface of the lower substrate can be substantially the same from center to periphery. Therefore, the tilt issue of the stacked structure due to stand-off deviation can be solved, and the reliability or performance of the semiconductor device package can be improved accordingly.

In some embodiments, a method for manufacturing a semiconductor device package according to the present disclosure includes providing a first substrate; providing an interposer; and forming a spacer in contact with the first substrate and the interposer.

The stage of forming a spacer in contact with the first substrate and the interposer includes placing a holder (or a set of holders) between the interposer and the first substrate to define an accommodation space for a conductive adhesive layer, and heating the conductive adhesive layer to form the spacer. In this stage, the soldering, conductive material is filled into the accommodation space and then heated to form the spacer. The height of the spacer can be predetermined and controlled by the holder. The soldering, conductive material is cured into a spacer having a predetermined height after heating and then the holder is removed. With the formation of a spacer with a predetermined height, a desirable distance between the interposer and the first substrate can be secured. In some embodiments, the distance between the interposer and the first substrate is substantially the same from the center of the interposer to the periphery of the interposer.

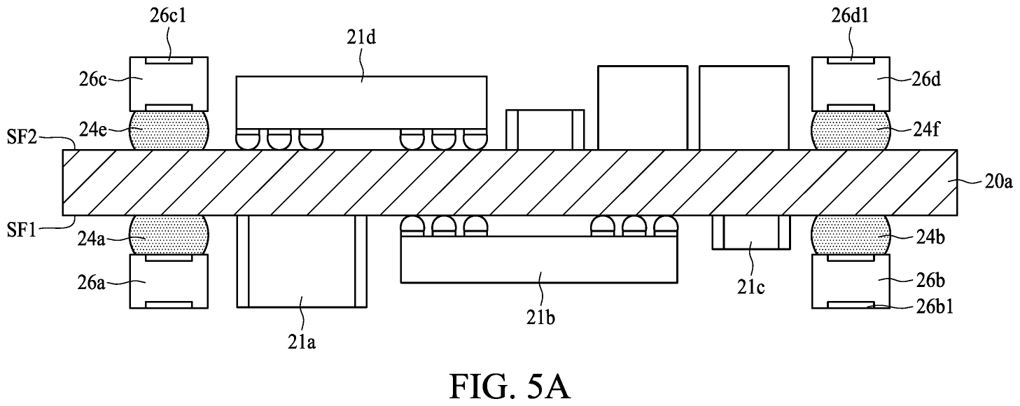

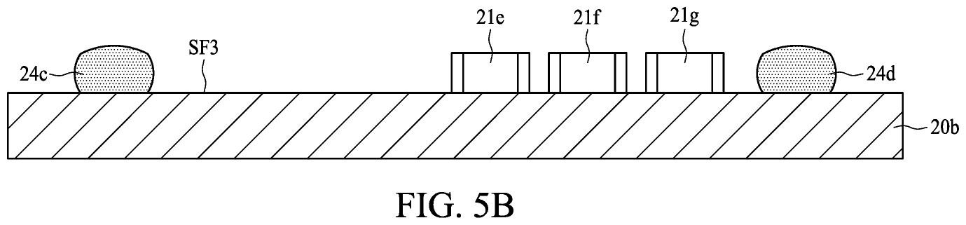

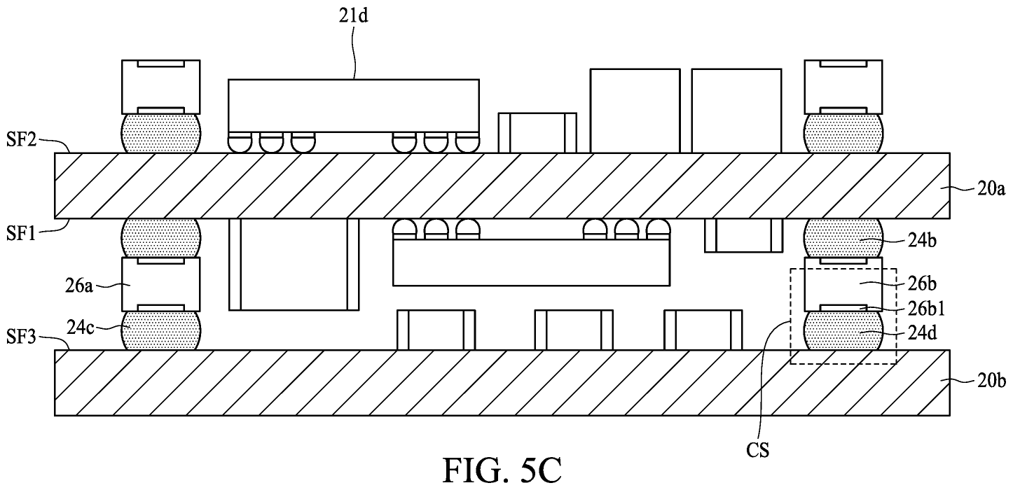

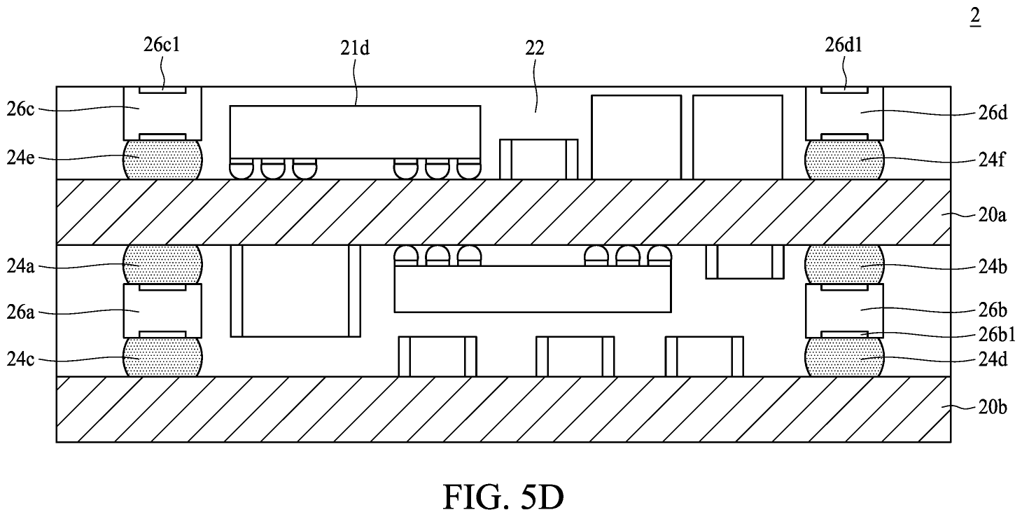

FIG. 5A, FIG. 5B, FIGS. 5C and 5D illustrate various stages of a method for manufacturing a semiconductor device package in accordance with some embodiments of the present disclosure.

Referring to FIG. 5A, a first substrate 20a having a first surface SF1 and a second surface SF2 opposing to the first surface SF1 is provided, and a first interposer and a second interposer are disposed on the first surface SF1 and the second surface SF2, respectively to form a unit device. The first interposers 26a and 26b are mounted to the first surface SF1 by the conductive adhesive layers 24a and 24b, respectively. The second interposers 26c and 26d are mounted to the second surface SF2 by the conductive adhesive layers 24e and 24f, respectively. In some embodiments, the conductive adhesive layers can be formed on a surface of the substrate, for example, by printing a solder, conductive material on a surface of the substrate. The soldering, conductive material may include a spacer. In some embodiments, the surface of the substrate may include recesses and the conductive adhesive layers fill a respective recess of the substrate. The interposers 26a, 26b, 26c and 26d can be disposed on the conductive adhesive layers 24a, 24b 24e and 24f, respectively, so that the conductive adhesive layers fills the recesses of a respective one of the interposers and each of the recesses accommodates one or more spacers. Then, the conductive adhesive layers 24a, 24b 24e and 24f are cured, for example, by heating or in a reflow process. Therefore, the gap between the substrate 20a and each of the interposers 26a, 26b, 26c and 26d can be controlled by the height of the spacer. The electronic components e.g., 21a, 21b and 21c, are formed or provided on the first surface SF1 and the electronic components e.g., 21d, are formed or provided on the second surface SF2.

Referring to FIG. 5B, a second substrate 20b having a surface SF3 is provided. The conductive adhesive layers 24c and 24d can be formed on the surface SF3 of the second substrate 20b, for example, by printing a solder, conductive material on the surface SF3. The soldering, conductive material may include a spacer. In some embodiments, the surface SF3 of the second substrate 20b may include recesses and the conductive adhesive layers fill a respective recess of the second substrate 20b. The electronic components e.g., 21e, 21f and 21g, are formed or provided on the surface SF3 of the second substrate 20b.

Referring to FIG. 5C, the unit device prepared in the stage illustrated in FIG. 5A is attached to the second substrate 20b by the conductive adhesive layers 24c and 24d. The interposers 26a and 26b mounted on the unit device can be disposed on the conductive adhesive layers 24c and 24d, respectively. Each of the interposers 26a and 26b may include recesses on its surface which is in contact with the conductive adhesive layers 24c and 24d. The conductive adhesive layers fill the recesses of the interposers and each of the recesses accommodates one or more spacers. Then, the conductive adhesive layers 24c and 24d are cured, for example, by heating or in a reflow process. Therefore, the gap between the second substrate 20b and each of the interposers 26a and 26b can be controlled by the height of the spacer.

Referring to FIG. 5D, an encapsulation layer 22 covers or encapsulates the electronic components 21a, 21b, 21c, 21d, 21e, 21f and 21g, the interposers 26a, 26b, 26c and 26d, the conductive adhesive layers 24a, 24b, 24c, 24d, 24e and 24f, the substrate 20a and the surface 20b.

Comparing with using solder paste, by using the conductive adhesive layers 24a, 24b, 24c, 24d, 24e and 24f, the present disclosure can keep the gap between the lower substrate 20b and the interposer 26a or 26b and the gap between the interposer 26a or 26b to the upper substrate 20a uniform, and therefore, the stand-off deviation can be reduced and the tilt of the upper substrate can be avoided. In addition, the conductive adhesive layers are made of solder, conductive material, for example, copper paste, which can be easily apply onto a surface and then cured by heating. Therefore, the number of the reflow processes can be reduced and the instability in height of the solder paste during the reflow processes can be obviated.

As used herein, spatially relative terms, such as “beneath,” “below,” “lower,” “above,” “upper,” “lower,” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As used herein, the terms “approximately,” “substantially,” “substantial” and “about” are used to describe and account for small variations. When used in conduction with an event or circumstance, the terms can refer to instances in which the event or circumstance occurs precisely, as well as instances in which the event or circumstance occurs to a close approximation. As used herein with respect to a given value or range, the term “about” generally means within ±10%, ±5%, ±1%, or ±0.5% of the given value or range. Ranges can be expressed herein as from one endpoint to another endpoint or between two endpoints. All ranges disclosed herein are inclusive of the endpoints, unless specified otherwise. The term “substantially coplanar” can refer to two surfaces within micrometers (μm) of lying along a same plane, such as within 10 μm, within 5 μm, within 1 μm, or within 0.5 μm of lying along the same plane. When referring to numerical values or characteristics as “substantially” the same, the term can refer to the values lying within ±10%, ±5%, ±1%, or ±0.5% of an average of the values.

The foregoing outlines the features of several embodiments and detailed aspects of the present disclosure. The embodiments described in the present disclosure may be readily used as a basis for designing or modifying other processes and structures for carrying out the same or similar purposes and/or achieving the same or similar advantages of the embodiments introduced herein. Such equivalent constructions do not depart from the spirit and scope of the present disclosure, and various changes, substitutions, and alterations may be made without departing from the spirit and scope of the present disclosure.

1. A semiconductor device package, comprising:
a first substrate; and
a first interposer;
wherein a bottom surface of the first interposer is attached to a top surface of the first substrate by a first conductive adhesive layer including a spacer.

2. The semiconductor device package of claim 1, wherein the first conductive adhesive layer is made of a soldering, conductive material including a spacer.

3. The semiconductor device package of claim 2, wherein the soldering, conductive material comprises a thermosetting resin and an electrically conductive material.

4. The semiconductor device package of claim 1, wherein the spacer is in direct contact with the first substrate and a respective first interposer.

5. The semiconductor device package of claim 1, wherein each of the first interposers comprises a plurality of pads at the bottom surface of the first interposer.

6. The semiconductor device package of claim 5, wherein the pads are arranged in a staggered manner.

7. The semiconductor device package of claim 5, wherein each of the first interposers comprises an insulation layer disposed at the bottom surface of the first interposer and covering the peripheral of pads, the insulation layer and a respective one of the pads defines a recess accommodating the first conductive adhesive layer.

8. The semiconductor device package of claim 1, further comprising a second substrate, wherein a top surface of the first interposer is attached to a bottom surface of the second substrate by a second conductive adhesive layer.

9. The semiconductor device package of claim 8, wherein the second conductive adhesive layer is made of a soldering, conductive material including a spacer.

10. The semiconductor device package of claim 1, wherein the top surface of the first substrate comprises one or more electronic components.

11. The semiconductor device package of claim 8, wherein the bottom surface of the second substrate comprises one or more electronic components.

12. The semiconductor device package of claim 8, wherein a distance between the bottom surface of the second substrate and the top surface of the first substrate is substantially the same from center to periphery.

13. The semiconductor device package of claim 8, wherein a top surface of the second substrate comprises one or more electronic components.

14. The semiconductor device package of claim 1, further comprising at least two first interposers separated apart from each other.

15. The semiconductor device package of claim 8, further comprising a second interposer attached to a top surface of the second substrate by a third conductive adhesive layer including a spacer.

16. The semiconductor device package of claim 15, further comprising an encapsulation layer encapsulating the first substrate, the second substrate, the first interposer, the second interposer, the first conductive adhesive layer, the second conductive adhesive layer and the third conductive adhesive layer.

17. The semiconductor device package of claim 16, wherein the encapsulation layer has a planar top surface and a pad of each of the second interposers is exposed from the top surface of the encapsulation layer.

18. A method of manufacturing a semiconductor device package, comprising:
providing a first substrate;
providing an interposer; and
forming a spacer in contact with the first substrate and the interposer.

19. The method of claim 18, wherein forming a spacer in contact with the first substrate and the interposer comprises:
placing a holder between a first surface of the interposer and a first surface of the first substrate to define an accommodation space for a conductive adhesive layer; and
heating the conductive adhesive layer to form the spacer.

20. The method of claim 19, further comprising securing a distance between the first surface of the interposer and the first surface of the first substrate is substantially the same from the center of the interposer to the periphery of the interposer.
